(19) United States
(12) Patent Application Publication
(10) Pub. No.: US 2011/0213578 A1
(43) Pub. Date: Sep. 1, 2011

(54) Signal Detection Device, Signal Detection Method, and Method of Manufacturing Signal Detection Device

(75) Inventors: Zhong Zhang, Aichi (JP); Tetsuo Miyake, Aichi (JP); Takashi Imamura, Aichi (JP)

(73) Assignee: National University Corporation Toyohashi University of Technology, Toyohashi-shi, Aichi (JP)

(21) Appl. No.: 13/122,958

(22) PCT Filed: Aug. 27, 2009
(86) PCT No.: PCT/JP2009/064929

§ 371 Date: May 5, 2011

(30) Foreign Application Priority Data
Oct. 9, 2008 (JP) 2008-262688

(51) Int. Cl. G06F 19/00; H05K 13/00

(52) U.S. Cl. 702/66; 29/592.1

(57) ABSTRACT

A signal detection device allows wavelet transformation of an object signal to be performed in real time by using a real signal mother wavelet. The signal detection device has: an object signal decomposition unit having a lifting scheme structure or a multiple analysis structure relying on multiresolution analysis; a parasitic filter coupled to a desired decomposition filter of the object signal decomposition unit, with the parasitic filter being configured such that a real signal mother wavelet is inputted to the object signal decomposition unit and a generic discrete wavelet transformation is performed, the parasitic filter substantially reproduces and outputs the inputted real signal mother wavelet, and with the real signal mother wavelet being made up of the object signal; means for inputting the object signal to the object signal decomposition unit and performing discrete wavelet transformation using the real signal mother wavelet; and means for computing a wavelet instantaneous correlation on the basis of an output of the parasitic filter.

### TECHNICAL FIELD

The present invention relates to a signal detection device that uses wavelet transformation.

### BACKGROUND ART

Conventionally, signal detection involves cross-correlation methods (Non-patent document 1), bandpass filters (Non-patent document 2) and pattern matching (Non-patent document 3). In a cross-correlation method, however, only an average result is obtained, and hence the method is unsuitable for detection of unsteady signals. In bandpass filter methods, multiple dissimilar bandpass filters must be arrayed in parallel to detect an object signal that comprises multiple characteristic components. Realizing such a method is thus difficult. Pattern matching methods are sensitive as regards the generation time of an object signal, but fail to detect the strength of the object signal.

Wavelet instantaneous correlation (WIC) using continuous wavelet transformation (CWT) has been proposed in order to overcome these drawbacks (Non-patent document 4, Patent document 1 and Patent document 2). Wavelet instantaneous correlation methods allow detecting simultaneously the generation time and the strength of an object signal, and are useful for detecting unsteady signals and for monitoring the state of equipment.

The continuous wavelet transformation (CWT) of an analysis signal f(t) is represented by Eq. (1)

There are defined:

$$\begin{matrix}[ Equation 1 ] & \\ w ( a , b ) = {\int }_{- ∞}^{∞} f ( t ) \overline{{ψ}_{a , b} ( t )} d t , \\ {ψ}_{a , b} ( t ) = {a}^{- 1 / 2} ψ ( \frac{t - b}{a} ) , & ( 1 )\end{matrix}$$

Herein, a)(a>0) denotes scale, i.e. 1/a corresponds to the frequency, b is a time parameter, and ψ̅_̅{̅a̅,̅b̅}̅(̅t̅)̅ is the complex conjugate of ψ_{a,b}(t).

The function Ψ(t), which is called a mother wavelet (MW), must satisfy the admissibility condition set forth in Eq. (2).

$$\begin{matrix}[ Equation 2 ] & \\ {C}_{ψ} = {\int }_{- ∞}^{∞} \frac{{\vert \hat{ψ} ( ω ) \vert}^{2}}{\vert ω \vert} d ω < ∞ . & ( 2 )\end{matrix}$$

Herein, \hat{ψ}(ω) is the Fourier transform of ψ(t), ω is the angular frequency (ω=2πf) and f is the frequency.

If Ψ(t) is a function that tends to zero sufficiently quickly at a distant point, Eq. (2) can be simplified to a fairly less strict condition, as given by Eq. (3) below.

[Equation 3]

∫_{-∞}^{∞}ψ(t)dt=0. (3)

In this sense, the range of selection of MW is rendered broader, and the construction thereof simpler.

There has also been proposed a method of detecting and evaluating an object signal, in an analysis signal, by constructing a mother wavelet (referred to hereafter as real signal mother wavelet, RMW) on the basis of the object signal, and defining a wavelet instantaneous correlation (WIC) R(b), between the analysis signal and the RMW, as |w(1,b)|, at a scale a=1, obtained by CWT using the RMW.

[Equation 4]

R(b)=|w(1,b)| (4)

The wavelet transformation is referred to as discrete wavelet transformation, for a scale a=2^{j} and time b=k2^{j} as parameters of the wavelet transformation. Unlike in the case of continuous wavelet transformation, a fast algorithm (Non-patent document 5) based on Mallat's multiresolution analysis (MRA), and a fast algorithm (Non-patent document 6) based on Sweldens' lifting scheme, have been proposed for discrete wavelet transformation (DWT).

FIG. 1 is a multiple analysis structure by Mallat's multiresolution analysis. FIG. 1(a) is a decomposition algorithm, and FIG. 1(b) is a reconstruction algorithm. In such DWT, a time-series signal is analyzed by octave analysis in the frequency domain. The octaves from the Nyquist frequency are notated as level −1, level −2, . . . . This algorithm involves fast calculation, on the basis of Eq. (5) and Eq. (6), of a scaling coefficient (low-frequency component) c_{-1,k} and a wavelet coefficient (high-frequency component) d_{-1,k} for level −1, on the basis of discrete data c_{0,k} of the analysis signal f(t) obtained firstly using a scaling function, by employing a dual two-scale sequence {aₖ} and a dual wavelet sequence {bₖ} alone.

$$\begin{matrix}[ Equation 5 ] & \\ {c}_{- 1 , n} = {\sum }_{k} {a}_{k} {c}_{0 , 2 n - k} & ( 5 ) \\ [ Equation 6 ] & \\ {d}_{- 1 , n} = {\sum }_{k} {b}_{k} {c}_{0 , 2 n - k} & ( 6 )\end{matrix}$$

In this calculation, c_{-2,k} and d_{-2,k} at level −2 can be calculated next, from c_{-1,k} at level −1, on the basis of Eq. (5) and Eq. (6), in accordance with the decomposition algorithm illustrated in FIG. 1(a). All the wavelet coefficients d_{j,k} can be worked out progressively.

Herein, the original c_{j+1,k} can be calculated quickly from d_{j,k} and c_{j,k} on the basis of Eq. (7) using the two-scale sequence {pₖ} and wavelet sequence {qₖ}.

$$\begin{matrix}[ Equation 7 ] & \\ {c}_{j + 1 , n} = {\sum }_{k} {g}_{n - 2 k} {c}_{j , k} + {\sum }_{k} {h}_{n - 2 k} {d}_{j , k} & ( 7 )\end{matrix}$$

The discrete data c_{0,k} of the source signal can be progressively restored, from d_{j+1,k} and c_{j+1,k}, on the basis of Eq. (7), following the reconstruction algorithm illustrated in FIG. 1(b).

FIG. 2 shows the structure of a lifting scheme. FIG. 2(a) illustrates a decomposition algorithm, and FIG. 2(b) illustrates a reconstruction algorithm. The various elements of FIG. 2 perform the following processes.

1) Split: an inputted analysis signal is decomposed into an odd-numbered sequence and an even-numbered sequence.

[Equation 8]

c_{even,k}^{j}=c₂ₖ^{j}, c_{odd,k}^{j}=c₂ₖ₊₁^{j}, k=0,1, (8)

2) Predict: a high-frequency component is obtained from the odd-numbered sequence, using the even-numbered sequence.

[Equation 9]

dₖ^{j-i}=c_{odd,k}^{j}−P(c_{even,k}^{j}) (9)

[Equation 10]

3) Update: a low-frequency component cₖ^{j-1} is obtained from the even-numbered sequence using dₖ^{j-1}.

cₖ^{j-1}=c_{even,k}^{j}+U(dₖ^{j-1}) (10)

P and U are functions (filters) determined on the basis of a mother wavelet (MW) (hereafter, base mother wavelet (BMW)).

The lifting scheme has various characteristics. One such advantageous characteristic is that down sampling is carried out first and a filtering process is carried out thereafter, unlike in multiresolution analysis (MRA) employed in conventional DWT. The computational complexity becomes thus comparatively smaller.

In the embodiments of the present invention, DWT calculation is performed using a lifting scheme. Needless to say, the calculation may also be carried out using a fast algorithm on the basis of a multiresolution analysis.

Refer to Non-patent document 7 concerning real signal mother wavelets.
Patent document 1: Japanese Patent Application Publication No. 2007-205885
Patent document 2: Japanese Patent Application Publication No. 2007-205886
Non-patent document 1: Manolakis, D. G., V. K. Ingle and S. M. Kogon, {Statistical and adaptive Signal Processing}, Artech House, p. 237, 2005.
Non-patent document 2: Lee, J. H., et al., A new knocking-detection method using cylinder pressure, block vibration and sound pressure signal from a SI engine, SAE paper no.981436, 1998.
Non-patent document 3: Zhang Z. and E. Tomita, A new diagnostic method of knocking in a spark-ignition engine using the wavelet transform, SAE paper no.2000-01-1801, 2000.
Non-patent document 4: ZHANG Zhong, IKEUCHI Hiroki, ISHII Hideaki, HORIHATA Satoshi, IMAMURA Takashi, MIYAKE Tetsuo, Real-Signal Mother Wavelet and Its Application on Detection of Abnormal Signal: Designing Average Complex Real-Signal Mother Wavelet and Its Application, Transactions of the Japan Society of Mechanical Engineers. C 73(730) (June 2007), pp. 1676-1683.
Non-patent document 5: Mallat, S. G., A wavelet tour of signal processing, Academic Press, 1999.
Non-patent document 6: Wim Sweldens, The lifting scheme: A custom-design construction of bi-orthogonal wavelets, Appl. Comput. Harmon. Anal, vol. 3, no. 2, pp. 186-200, 1996
Non-patent document 7: Transactions of the Japan Society of Mechanical Engineers. C 73(730) (June 2007).

### DISCLOSURE OF THE INVENTION

An advantageous feature of current object signal detection methods based on wavelet instantaneous correlation WIC that rely on continuous wavelet transformation is that the generation time and the strength of an object signal are detected simultaneously. However, the computational complexity involved is substantial, since continuous wavelet transformation is employed, and hence, signal detection in real time is difficult.

In DWT using a lifting scheme, meanwhile, the MW that is employed must satisfy the bi-orthogonality condition, and only a limited number of MWs can be used. An RMW constructed on the basis of actually measured object signals does not satisfy the bi-orthogonality condition, and hence cannot be employed in discrete wavelet transformation.

It has been proposed to use fast algorithms, based on Mallat's fast algorithm, in DWT. However, as in the case of lifting schemes, the MW that is used must satisfy the bi-orthogonality condition, and thus only a limited number of MWs can be used. In particular, an RMW constructed on the basis of actually measured object signals does not satisfy the bi-orthogonality condition, and hence cannot be employed in discrete wavelet transformation.

In the light of the above, it is an object of the present invention to enable wavelet transformation of object signals in real time, using a real signal mother wavelet.

In order to solve the above problems, the present invention has the features below. Specifically,

a signal detection device, having:

an object signal decomposition unit that is formed by coupling a plurality of decomposition filters and that decomposes an object signal, with a coupled body of the decomposition filters being configured to make up part or the entirety of a discrete wavelet transformation tree;

a parasitic filter coupled to a desired decomposition filter of the object signal decomposition unit, with the parasitic filter being configured such that when a real signal mother wavelet is inputted to the object signal decomposition unit and a generic discrete wavelet transformation is performed, the parasitic filter substantially reproduces and outputs the inputted real signal mother wavelet, and with the real signal mother wavelet being made up of the object signal;

means for inputting the object signal to the object signal decomposition unit and performing the discrete wavelet transformation by using the real signal mother wavelet; and

means for computing a wavelet instantaneous correlation on the basis of an output of the parasitic filter.

A first aspect of the invention thus defined enables discrete wavelet transformation of an object signal in real time, by using a real signal mother wavelet.

### BRIEF DESCRIPTION OF THE DRAWINGS

FIG. 1 is a block diagram illustrating the structure of Mallat's fast algorithm;

FIG. 2 is a block diagram illustrating the structure of a lifting scheme;

FIG. 3 is a block diagram illustrating a configuration of parasitic filters coupled to a discrete wavelet tree structure;

FIG. 4 is a block diagram for explaining a design concept of a parasitic filter;

FIG. 5 is a flowchart illustrating a method of specifying a parasitic level;

FIG. 6 is a graph illustrating the frequency dependence of energy loss;

FIG. 7 is a graph illustrating the frequency dependence of power spectrum ratio;

FIG. 8 is a chart illustrating a comparison between a fast wavelet instantaneous correlation obtained by performing parasitic discrete wavelet transformation in an embodiment, and a wavelet instantaneous correlation obtained by performing a continuous wavelet transformation in a comparative embodiment;

FIG. 9 illustrates characteristics of a parasitic filter in an embodiment; and

FIG. 10 illustrates a frequency characteristic of an average real signal mother wavelet used in the embodiment;

### EXPLANATION OF REFERENCE NUMERALS

10 object signal decomposition unit (lifting scheme structure)
20 parasitic filter

### BEST MODE FOR CARRYING OUT THE INVENTION

Lifting scheme structures and multiresolution analysis are known schemes for discrete wavelet transformation, but the former scheme is preferably used, from the viewpoint of enhancing computational speed.

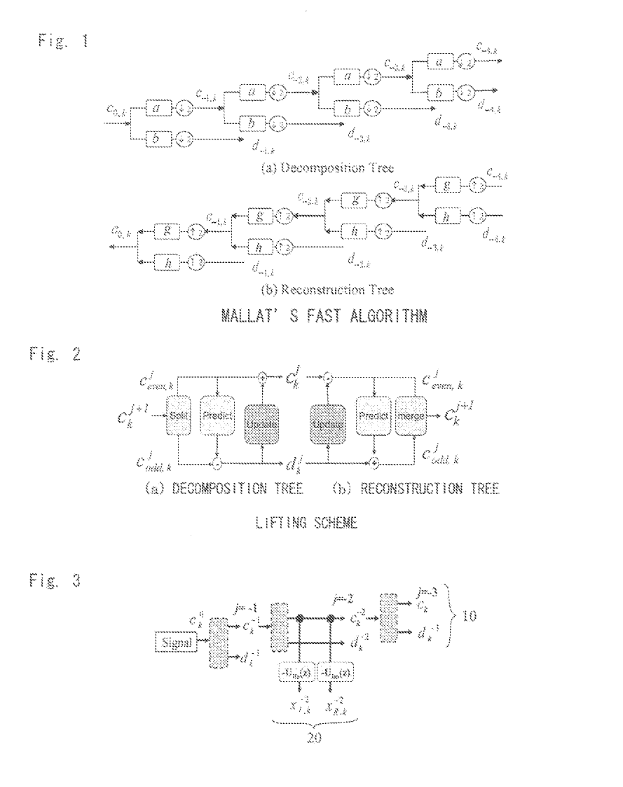

A decomposition algorithm in a lifting scheme structure is illustrated in FIG. 2. As indicated by the broken line of FIG. 3, the decomposition algorithm is embodied in an object signal decomposition unit 10 that is coupled to a tree structure. In the present description, each decomposition algorithm will be called a “decomposition filter”. A decomposition algorithm by a multiresolution analysis corresponds to a decomposition filter.

In FIG. 3, a generic tree of the lifting scheme structure can be used, as-is, as the object signal decomposition unit 10. This can be omitted in decomposition filters at a deeper level than that of the decomposition filter coupled to the parasitic filter 20.

An explanation follows next on a real signal mother wavelet (in the present description also notated as “RMW”).

The real signal mother wavelet used in the present invention is constructed in accordance with the below-described procedure, and is termed symmetric complex real signal mother wavelet (SC-RMW).

(1) A sampling frequency fₛ and a lowest frequency fₘᵢₙ of a characteristic portion are acquired from an object signal. The length of RMW is decided according to the following equation.

$$\begin{matrix}[ Equation 11 ] & \\ L > 3 \frac{{f}_{s}}{{f}_{min}} & ( 11 )\end{matrix}$$

(2) A characteristic portion is cut out from the object signal by a length L, followed by multiplication by a window function (for instance a Hanning window) such that the result tends quickly to zero at a distant point, to remove an average value. As a result there is constructed a real-number real signal mother wavelet.

[Equation 12]

(3) The RMW ψ^{R}(t)W is normalized in such a manner that the norm ∥ψ^{R}∥ is 1.

∥ψ^{R}(t)∥=∫_{-∞}^{∞}[ψ^{R}(t)²]^{1/2}dt (12)

(4) The Fourier transform of RMW ψ^{R}(t) yields a spectrum \hat{ψ}^{R}(f).

4) In the positive frequency domain, \hat{ψ}(f)=2\hat{ψ}^{R}(f). In the negative frequency domain, \hat{ψ}(f) is set to 0. For a frequency f=0, \hat{ψ}(f)=\hat{ψ}^{R}(f).

[Equation 13]

(5) Further, the real part is set to \hat{ψ}ᵣ(f)={square root over ((\hat{ψ}ᵣ^{R}(f))²+(\hat{ψ}ₗ^{R}(f))²)}, and the imaginary part to 0, to eliminate thereby the phase information in all the frequency components of \hat{ψ}(f).

(6) SC-RMW ω(t)=ψᵣ(t)+iψₗ(t) is obtained through inverse Fourier transform of \hat{ψ}(f).

Phase information is cancelled in step (5) above. Therefore, the obtained symmetric complex real signal mother wavelets (SC-RMW) can be added to each other.

Accordingly, respective symmetric complex real signal mother wavelets (SC-RMW) are constructed on the basis of a plurality of regions (characteristic portions) of the object signal. The constructs can be added and can be normalized (averaged). The result is called an average real signal mother wavelet (A-RMW). The average real signal mother wavelet (A-RMW) reflects broadly the characteristics of the object signal. Therefore, it becomes possible to detect components in the signal that could not be detected on the basis of a single symmetric complex real signal mother wavelet (SC-RMW). A more accurate wavelet transformation can be performed as a result.

In step (4) of the method of constructing the above-described real signal mother wavelet there are obtained complex real signal mother wavelets. These complex real signal mother wavelets comprise phase information. Therefore, although a process for, for instance, adding complex real signal mother wavelets to each other is difficult, such a process may, if simple, be used in the present invention.

The real signal mother wavelet (RMW) that can be used in the present invention, specifically, may be a symmetric complex real signal mother wavelet (SC-RMW), an average real signal mother wavelet (A-RMW) and a complex real signal mother wavelet (C-RMW). In the present description the foregoing are collectively referred to as real signal mother wavelet (RMW).

A parasitic filter design method is explained next.

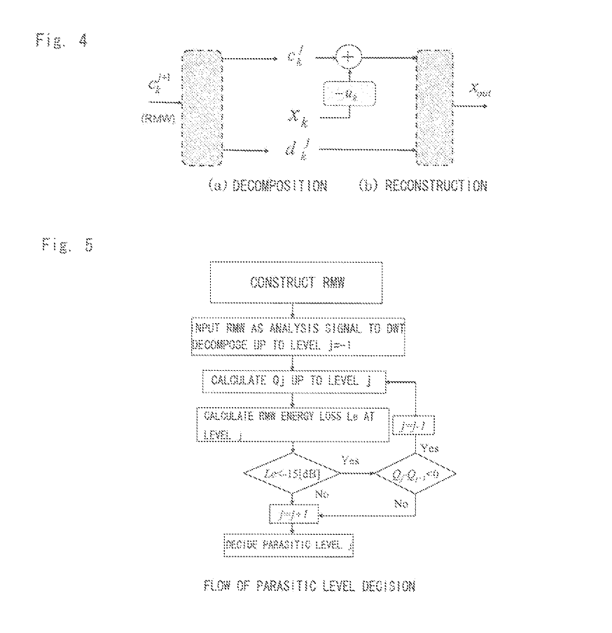

FIG. 4 illustrates a tree for design of a parasitic filter on the basis of RMWs. The shaded portion in the figure corresponds to the portion (decomposition algorithm) in FIG. 2(a). FIG. 4(b) is a reconstruction portion.

(1) A real signal mother wavelet RMW, as an object signal, is decomposed, by ordinary DWT, down to a parasitic level, in accordance with FIG. 4(a). The mother wavelet used at this time is a base mother wavelet (BMW), which is generically used in discrete wavelet transformation.

(2) The obtained coefficient c^{j}ₖ is set as the initial value of the parasitic filter {uₖ}.

(3) Reconstruction is performed using the reconstruction algorithm of FIG. 4(b), with c^{j}ₖ=0, d^{j}ₖ=0, Xₖ=δₖ, (wherein δₖ=1 (k=0), δₖ=0 (k≠0)), to obtain xₒᵤₜ.

(4) A generic optimization algorithm is used to optimize {uₖ}, in such a manner that ∥xₒᵤₜ−RMW∥ is minimal.

Specifically, in FIG. 3 there is compared the real signal mother wavelet against the output xₒᵤₜ of the parasitic filter at the time of input of the real signal mother wavelet RMW, as an object signal, to the discrete wavelet transformation tree. The {uₖ} at a time where the output xₒᵤₜ and the real signal mother wavelet substantially match each other is taken as the parasitic filter.

(5) In a case where the real signal mother wavelet RMW is a complex number, there must be designed parasitic filters {U_{R, k}} {u_{I, k}} that correspond respectively to the real part and the imaginary part of the RMW. Herein it is sufficient to carry out the above procedure for the real part and the imaginary part of the RMW.

The parasitic filter thus designed reproduces a real signal mother wavelet upon input of the real signal mother wavelet. Upon input of an object signal to be inspected, there is accordingly outputted a correlation between the object signal and the real signal mother wavelet.

During discrete wavelet transformation, thus, an arbitrarily constructed real signal mother wavelet can be used as-is, without requirements such as a bi-orthogonality condition in the mother wavelet.

Also, computational complexity can be reduced and process speed increased, as compared with a continuous wavelet, also in case that the parasitic filter is coupled to any decomposition filter in a discrete wavelet transformation tree. Real time processing can be realized as a result.

An explanation follows next on a method of specifying a decomposition filter to which a parasitic filter is to be coupled, in other words, for specifying the parasitic level of a parasitic filter.

Ordinarily, computational speed increases when the parasitic level to which the parasitic filter is associated becomes somewhat high. However, an excessively high parasitic level entails greater computational complexity, which in turn causes computational speed to drop. At the same time, the filter coefficients may decrease, as a result of which detection precision may drop on account of shape collapse. In order to preserve detection credibility, a parasitic level evaluation parameter and an RMW energy loss Le are defined as per Eq. (14).

$$\begin{matrix}[ Equation 14 ] & \\ Le = 10 {log}_{10} ( \frac{{\sum }_{j} {\sum }_{k} {( {d}_{k}^{j} )}^{2}}{{‖ ψ ( t ) ‖}^{2}} ) [ dB ] & ( 14 )\end{matrix}$$

In the case of the parasitic discrete wavelet transformation illustrated in FIG. 3, sufficient detection precision is obtained at a parasitic level that satisfies condition: Le≦−15 (dB). By contrast, detection precision drops somewhat, although fast design is possible, at a parasitic level that satisfies condition: −15 (dB)<Le≦−10 (dB).

The number of multiplications for analyzing the analysis signal to a level j is defined, as the computational complexity, according to the equation below.

$$\begin{matrix}[ Equation 15 ] & \\ {Q}_{j} = 10 {\sum }_{i = - 1}^{j} {2}^{i + 1} + {2}^{j + 1} L + 4 & ( 15 )\end{matrix}$$

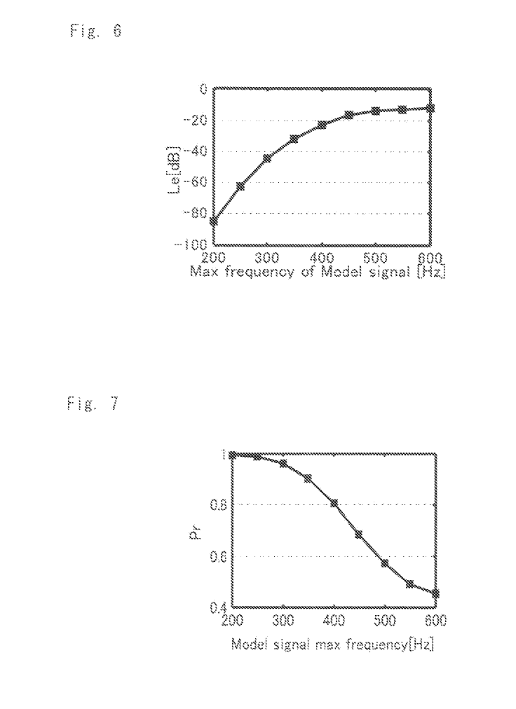

The flow for deciding the parasitic level using the RMW energy loss Le and the computational complexity Qⱼ follows the sequence below, illustrated in FIG. 5.

(1) The RMW constructed in step 1 is inputted, as an analysis signal, to the DWT, and is analyzed up to level j=−1.

(2) The computational complexity Qⱼ up to level j is calculated.

(3) The RMW energy loss Le up to level j is calculated.

It is checked whether condition: Le≦−15 (dB) is satisfied or not. If the condition is satisfied, there is further obtained a computational complexity difference Qⱼ−Qⱼ₊₁. If computational complexity decreases, the level j is advanced to one deeper level (j=j−1), the process returns to 2), and 2)-4) are repeatedly carried out. If computational complexity increases, the level j is returned to one shallower level (j=j+1), and that level is outputted as the parasitic level. If the condition: Le≦−15 (dB) is not satisfied, the level j is returned to one shallower level (j=j+1), and that level is outputted as the parasitic level.

A real signal mother wavelet was constructed using a model signal resulting from varying the maximum frequency of the three terms in f(x)=sin(2π50t)+0.7 sin(2π100t)+0.7 sin(2π200t) by intervals of 50 Hz, in a range from 200 Hz to 600 Hz, at a sampling frequency of 3500 Hz and an RMW length L=512. Discrete wavelet transformation was performed using this real signal mother wavelet as an object signal, and the energy loss Le was computed at level −2. The results are illustrated in FIG. 6.

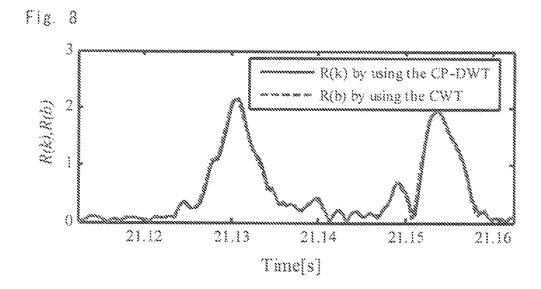

The parasitic filter was coupled to the high-frequency side of level −2, to compute the power spectrum ratio Pr. The results are illustrated in FIG. 7.

$$\begin{matrix}[ Equation 16 ] & \\ Pr = \frac{\sum {\vert {x}_{out} ( f ) \vert}^{2}}{\sum {\vert RMW ( f ) \vert}^{2}} \times 100 [ \% ] & ( 16 )\end{matrix}$$

Herein, the power spectrum ratio Pr denotes “to what extent the frequency component in the output of the parasitic filter has an RMW frequency component inputted as an object signal”. Specifically, RMW reproducibility by the parasitic filter is lower when Pr is small. Studies by the inventors have revealed that the frequency component in the output of a parasitic filter can be deemed to encompass substantially the entirety of the frequency component of the inputted RMW if the power spectrum ratio Pr is 95% or higher. In other words, the inputted RMW can be reproduced substantially entirely, as the output of the parasitic filter, if the power spectrum ratio Pr is 95% or higher.

FIG. 6 and FIG. 7 show the high degree of association between energy loss Le and power spectrum ratio Pr. The relationships in FIG. 6 and FIG. 7 show that a power spectrum ratio Pr=95% corresponds to an energy loss =−15 dB.

This indicates that, preferably, a parasitic filter is rendered parasitic at a level such that the energy loss Le is −15 dB or higher. The energy loss Le can be computed prior to the design of the parasitic filter. Therefore, the parasitic level of the parasitic filter can be specified by computing the energy loss Le at each level in the discrete wavelet transformation tree.

Computational speed can be made faster by reducing the computational complexity Qⱼ. Preferably, there is searched a parasitic level such that computational complexity is minimal, provided that the energy loss does not reach into −15 dB.

Object Signal Detection

An object signal is detected by obtaining a fast wavelet instantaneous correlation by parasitic discrete wavelet transformation, on the basis of the procedure set forth below, according to the decomposition tree of the parasitic discrete wavelet transformation illustrated in FIG. 3.

(1) The analysis signal is decomposed by DWT up to the parasitic level, to obtain c^{j}ₖ and d^{j}ₖ.

(2) A frequency component in RMW is extracted by way of the parasitic filters {u_{R, k}} and {u_{I, k}}, from among the frequency components in c^{j}ₖ, to obtain x^{j}_{R, k} and x^{j}_{I, k}.

The wavelet instantaneous correlation defined by Eq. (17) below is obtained, whereupon the object signal is detected using the instant (k) or the size |R(k)| of the wavelet instantaneous correlation value.

[Equation 17]

R(k)=\sqrt{(x_{R,k}^{j})²+(x_{1,k}^{j})²} (17)

This R(k) is referred to as a fast wavelet instantaneous correlation.

A comparison was performed between the fast wavelet instantaneous correlation and the wavelet instantaneous correlation R(t) obtained by continuous wavelet transformation (CWT).

As a noise source search in power steering devices, the inventors have constructed an average real signal mother wavelet from eight rattle noises, to obtain a wavelet instantaneous correlation of a continuous wavelet transformation (CWT) using the average real signal mother wavelets (JSME C, 73-730, pp. 1676-1683 (2007)).

The present invention was used in the same noise sources to obtain a fast wavelet instantaneous correlation. Both correlations matched each other completely, as illustrated in FIG. 8. Upon execution of the processes in a same computer, the computation time in the embodiment of the present invention was about 35% of the computation time in the former instance (CWT).

When the present invention was used, the maximum frequency in the eight rattle noises was 2000 Hz and the sampling frequency was 12000 Hz. Therefore, SC-RMWs were constructed from the eight rattle noises, with an RMW length of 128, and an average real signal mother wavelet (A-RMW) was constructed through addition and normalization (averaging) of each SC-RMW. The method illustrated in FIG. 5 was applied to this A-RMW, whereupon it was found that a parasitic level −2 was appropriate.

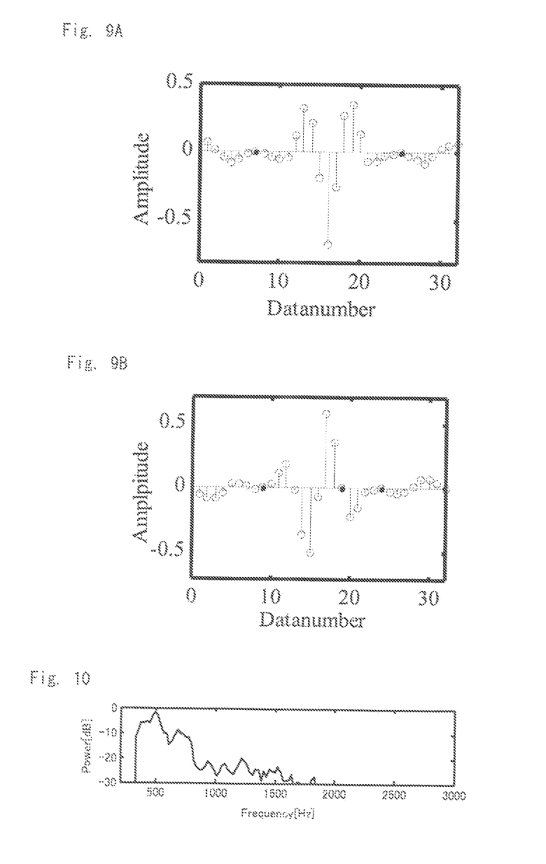

The designed parasitic filter is illustrated in FIG. 9. FIG. 9(A) illustrates a real-part parasitic filter, FIG. 9(B) an imaginary-part parasitic filter, and FIG. 10 illustrates a frequency characteristic of an average real signal mother wavelet.

In the above-described examples, the parasitic filter is connected to a high-frequency component side, but may also be connected to a low-frequency component side.

The object signal to be inspected is not limited to sound. The object of inspection may be, for instance, the change over time of any physical phenomenon, such as vibration, temperature changes or the like, as well as other changes in phenomena that can be represented in the form of analog waveforms.

The parasitic filter may also be referred to as “auxiliary filter” or “anomaly detection filter”.

The object signal decomposition unit and the parasitic filter have been represented in the form of block diagrams, but are performed through installation of a predetermined program in a general-purpose computer device. An interface (microphone or the like) for introducing the object signal is provided in such a computer device. A display and/or printer for outputting the wavelet instantaneous correlation are also provided.

The present invention is not limited to the above-described embodiments and examples. The invention can accommodate, without departing from the scope of the appended claims, various modifications that a person skilled in the art could easily conceive of.

1. A signal detection device, comprising:
an object signal decomposition unit that is formed by coupling a plurality of decomposition filters and that decomposes an object signal, with a coupled body of the decomposition filters being configured to make up part or the entirety of a discrete wavelet transformation tree;
a parasitic filter coupled to a desired decomposition filter of the object signal decomposition unit, with the parasitic filter being configured such that when a real signal mother wavelet is inputted to the object signal decomposition unit and a generic discrete wavelet transformation is performed, the parasitic filter substantially reproduces and outputs the inputted real signal mother wavelet, and with the real signal mother wavelet being made up of the object signal;
a device for inputting the object signal to the object signal decomposition unit and performing the discrete wavelet transformation by using the real signal mother wavelet; and
a device for computing a wavelet instantaneous correlation on the basis of an output of the parasitic filter, wherein
the parasitic filter has a real part and an imaginary part and is coupled to the decomposition filter so as to satisfy the conditions below:
(1) the generic discrete wavelet transformation is performed by inputting the real signal mother wavelet to the discrete wavelet transformation tree, and an energy loss of the real signal mother wavelet in the decomposition filter to which the parasitic filter is coupled is not greater than 15 dB; and
(2) computational complexity is minimized while satisfying the condition (1).

2. The signal detection device according to claim 1, wherein the discrete wavelet transformation tree has a lifting scheme structure.

3. The signal detection device according to claim 1, wherein the real signal mother wavelet is a complex number mother wavelet.

4. The signal detection device according to claim 1, wherein the real signal mother wavelet is an average real signal mother wavelet.

5. A method of manufacturing a signal detection device,
the method comprising:
a step of constructing a real signal mother wavelet from an object signal;
a step of preparing a discrete wavelet transformation tree by coupling a plurality of decomposition filters;
a step of coupling a parasitic filter to one of the decomposition filters; and
a step of optimizing the parasitic filter such that when the real signal mother wavelet is inputted to the discrete wavelet transformation tree and a generic discrete wavelet transformation is performed, the real signal mother wavelet is substantially reproduced by the parasitic filter, wherein
the parasitic filter has a real part and an imaginary part, and is coupled to the decomposition filter so as to satisfy the conditions below:
(1) the real signal mother wavelet is inputted to the discrete wavelet transformation tree and the generic discrete wavelet transformation is performed, and an energy loss of the real signal mother wavelet in the decomposition filter to which the parasitic filter is coupled is not greater than 15 dB; and
(2) computational complexity is minimized while satisfying the condition (1).

6. The method of manufacturing a signal detection device according to claim 5, wherein the real signal mother wavelet is a complex number real signal mother wavelet.

7. The method of manufacturing a signal detection device according to claim 5, wherein the real signal mother wavelet is an average mother wavelet.

8. The method of manufacturing a signal detection device according to claim 5, wherein
the energy loss Le of the real signal mother wavelet is given by Equation 14
$$Le = 10 {log}_{10} ( \frac{{\sum }_{j} {\sum }_{k} {( {d}_{k}^{j} )}^{2}}{{‖ ψ ( t ) ‖}^{2}} ) [ dB ] \qquad ( 14 )$$
where the function Ψ(t) represents the real signal mother wavelet, d represents a wavelet coefficient, and j and k represent a level and discrete time of the decomposition filter to which the parasitic filter is coupled.

9. The method of manufacturing a signal detection device according to claim 8, wherein the computational complexity Qj is given by Equation 15
$${Q}_{j} 10 {\sum }_{i = - 1}^{j} {2}^{i + 1} + {2}^{j + 1} L + 4 \qquad ( 15 )$$
where i and j represent levels of the decomposition filter to which the parasitic filter is coupled.

10. The method of manufacturing a signal detection device according to claim 5, wherein the discrete wavelet transformation tree has a lifting scheme structure.

11. (canceled)
